(19) United States
(12) Patent Application Publication
(10) Pub. No.: US 2025/0377568 A1
(43) Pub. Date: Dec. 11, 2025

(54) ACTIVE MATRIX SUBSTRATE, LIQUID CRYSTAL DISPLAY DEVICE, AND METHOD FOR MANUFACTURING ACTIVE MATRIX SUBSTRATE

(71) Applicant: Sharp Display Technology Corporation, Kameyama City (JP)

(72) Inventors: Atsushi HACHIYA, Kameyama City (JP); Yuhichi SAITOH, Kameyama City (JP)

(21) Appl. No.: 19/214,198

(22) Filed: May 21, 2025

(30) Foreign Application Priority Data
Jun. 11, 2024 (JP) 2024-094316

(51) Int. Cl. G02F 1/1362; G02F 1/1368; H10D 86/01; H10D 86/40; H10D 86/60

(52) U.S. Cl. CPC G02F 1/136227; G02F 1/1368; H10D 86/0221; H10D 86/423; H10D 86/60

(57) ABSTRACT

An active matrix substrate includes a substrate, TFTs, an insulating layer covering the TFTs, a flattened layer covering the insulating layer, pixel electrodes located on the flattened layer, and connection electrodes located between the insulating layer and the flattened layer respectively. The TFT includes a gate electrode, a gate insulating layer, and an oxide semiconductor layer. The oxide semiconductor layer includes a channel region facing the gate electrode with the lower gate insulating layer interposed therebetween, a source region and a drain region positioned on either side of the channel region. The insulating layer includes a contact hole at a position overlapping the drain region. The connection electrode is connected to the drain region in the contact hole. The drain region has a higher impurity concentration at least in a portion overlapping the contact hole than a concentration in a portion adjacent to the channel region.

### CROSS-REFERENCE TO RELATED APPLICATIONS

This application claims the benefit of priority to Japanese Patent Application Number 2024-094316 filed on Jun. 11, 2024. The entire contents of the above-identified application are hereby incorporated by reference.

### BACKGROUND

### Technical Field

The technology disclosed in this specification relates to an active matrix substrate, a liquid crystal display device, and a method for manufacturing an active matrix substrate.

At present, a liquid crystal display device including an active matrix substrate is being widely used for various purposes. The active matrix substrate includes switching elements, such as thin film transistors (TFTs) for pixel electrodes, respectively. The pixel electrode and the TFT are insulated from each other by a passivation layer (inorganic insulating layer) and a flattened layer (organic insulating film). The pixel electrode and a drain electrode of the TFT are electrically connected through a contact hole provided in these layers.

### SUMMARY

As resolution of liquid crystal display devices is increasing year by year, the flattened layer is sometimes formed thicker than before (e.g., 4 to 5 μm) in order to sufficiently flatten a surface on which the pixel electrodes are mounted and to suppress generation of load capacitance. Providing deep contact holes in a thick flattened layer increases an area occupied by a tapered portion of each contact hole, which is undesirable in terms of achieving high definition and increasing an aperture ratio. In response to this, JP 2017-187714 A discloses a configuration in which a bottom of a contact hole is raised by a pedestal portion to make the contact hole shallower. However, a structure with the pedestal portion and a metal portion covering the pedestal portion has room for improvement in terms of increasing the aperture ratio.

The disclosure has been made in consideration of the above-mentioned problems, and an object of the disclosure is to provide an active matrix substrate having an improved contact structure between a pixel electrode and a TFT.

The specification discloses an active matrix substrate, a liquid crystal display device, and a method for manufacturing an active matrix substrate, as described in the following items.

### Configuration 1

An active matrix substrate including a display region including a plurality of pixel regions, the active matrix substrate including a substrate, thin film transistors (TFTs) supported by the substrate and located in the plurality of pixel regions, respectively, an insulating layer covering the TFTs, a flattened layer covering the insulating layer, pixel electrodes located on the flattened layer, and connection electrodes located between the insulating layer and the flattened layer, and configured to electrically connect the TFTs and the pixel electrodes, respectively, in which each of the TFTs includes a gate electrode, a gate insulating layer configured to electrically insulate the gate electrode, and an oxide semiconductor layer including a channel region facing the gate electrode with the gate insulating layer interposed between the channel region and the gate electrode, and a source region located on one side of the channel region and a drain region located on another side of the channel region, the insulating layer includes a contact hole at a position overlapping with the drain region, the connection electrodes are formed from a transparent conductive material and each of the connection electrodes is connected to the drain region in the contact hole, and the drain region has a higher concentration of impurities at least in a portion overlapping the contact hole than a concentration in a portion adjacent to the channel region.

### Configuration 2

The active matrix substrate according to configuration 1, in which each of the impurities is at least one of group 13 elements and group 15 elements.

### Configuration 3

The active matrix substrate according to configuration 1 or 2, in which the connection electrodes include at least one of indium tin oxide (ITO) and indium zinc oxide (IZO), and the oxide semiconductor layer includes an In—Ga—Zn—O-based oxide semiconductor.

### Configuration 4

The active matrix substrate according to any one of configurations 1 to 3, in which as viewed from a normal direction of the substrate, the flattened layer includes pixel contact holes, each of the pixel contact holes being configured to connect each of the pixel electrodes and each of the connection electrodes at a position at least partially overlapping with the gate electrode.

### Configuration 5

The active matrix substrate according to configuration 4, in which, as viewed from the normal direction of the substrate, a bottom face of each of the pixel contact holes at least partially overlaps a gate metal layer including the gate electrode.

### Configuration 6

The active matrix substrate according to configuration 4 or 5, in which a portion of each of the pixel electrodes is in contact with each of the connection electrodes in each of the pixel contact holes.

### Configuration 7

The active matrix substrate according to any one of configurations 4 to 6, further includes other connection electrodes formed from a transparent conductive material and configured to electrically connect the connection electrodes and the pixel electrodes, respectively, each of the other connection electrodes being in contact with each of the connection electrodes in each of the pixel contact holes, and another flattened layer configured to fill the pixel contact holes and cover portions of the other connection electrodes, in which each of the pixel electrodes is in contact with a portion of each of the other connection electrodes, the portion being not covered with the other flattened layer, and each of the pixel electrodes includes a portion located on the other flattened layer.

### Configuration 8

The active matrix substrate according to configuration 7, in which the other connection electrodes and the pixel electrodes are formed from the same transparent conductive material.

### Configuration 9

The active matrix substrate according to configuration 7 or 8, in which the other connection electrodes and the pixel electrodes are formed from at least one of indium tin oxide and indium zinc oxide.

### Configuration 10

The active matrix substrate according to any one of configurations 1 to 9, in which each of the TFTs includes a lower gate electrode located on the substrate, a lower gate insulating layer covering the lower gate electrode, the oxide semiconductor layer, the channel region of the oxide semiconductor layer being located on the lower gate insulating layer, an upper gate insulating layer located on the channel region of the oxide semiconductor layer, and an upper gate electrode located on the upper gate insulating layer and facing the channel region of the oxide semiconductor layer with the upper gate insulating layer interposed between the upper gate electrode and the channel region.

### Configuration 11

The active matrix substrate according to configuration 10, in which, as viewed from the normal direction of the substrate, the flattened layer includes pixel contact holes, each of the contact holes being configured to electrically connect each of the pixel electrodes and each of the connection electrodes at a position at least partially overlapping with the upper gate electrode, and a bottom face of each of the pixel contact holes at least partially overlaps both the lower gate electrode and the upper gate electrode.

### Configuration 12

A liquid crystal display device including the active matrix substrate according to any one of configurations 1 to 11, a counter substrate located facing the active matrix substrate, and a liquid crystal layer located between the active matrix substrate and the counter substrate.

### Configuration 13

A method for manufacturing an active matrix substrate, including forming a thin film transistor (TFT) on a substrate, the TFT including a gate electrode, a gate insulating layer configured to electrically insulate the gate electrode, and an oxide semiconductor layer including a channel region facing the gate electrode with the gate insulating layer interposed between the channel region and the gate electrode, and a source region located on one side of the channel region and a drain region located on another side of the channel region, forming an insulating layer on the TFT, forming a contact hole in the insulating layer, the contact hole being configured to reach the drain region, doping impurities through the contact hole into a portion of the drain region overlapping the contact hole, forming a connection electrode on the insulating layer at least from the contact hole to a position overlapping the gate electrode, the connection electrode being configured to electrically connect the TFT and a pixel electrode, and forming a flattened layer on the insulating layer and the connection electrode.

### Configuration 14

The method for manufacturing an active matrix substrate according to configuration 13, in which the TFT includes a lower gate electrode located on the substrate, a lower gate insulating layer covering the lower gate electrode, the oxide semiconductor layer, the channel region of the oxide semiconductor layer being located on the lower gate insulating layer, an upper gate insulating layer located on the channel region of the oxide semiconductor layer, and an upper gate electrode located on the upper gate insulating layer and facing the channel region of the oxide semiconductor layer with the upper gate insulating layer interposed between the upper gate electrode and the channel region, the method including forming the connection electrode on the insulating layer at least from the contact hole to a position overlapping the upper gate electrode.

### Configuration 15

The method for manufacturing an active matrix substrate according to configuration 14, further including forming a pixel contact hole in the flattened layer at a position overlapping the gate electrode or the upper gate electrode and the connection electrode, the pixel contact hole reaching the connection electrode, and forming a pixel electrode on the flattened layer at a position at least partially overlapping the connection electrode through the pixel contact hole.

### Configuration 16

The method for manufacturing an active matrix substrate according to configuration 14 or 15, further including forming a pixel contact hole in the flattened layer at a position overlapping the gate electrode or the upper gate electrode and the connection electrode, the pixel contact hole reaching the connection electrode, forming another connection electrode on the flattened layer at a position at least partially overlapping the connection electrode through the pixel contact hole, forming another flattened layer configured to fill the pixel contact hole, and forming a pixel electrode on at least one of the flattened layer and the other flattened layer at a position at least partially overlapping the other connection electrode.

According to embodiments of the disclosure, it is possible to provide an active matrix substrate having an improved contact structure between a pixel electrode and a TFT.

### BRIEF DESCRIPTION OF DRAWINGS

The disclosure will be described with reference to the accompanying drawings, wherein like numbers reference like elements.

FIG. 1 is a schematic diagram illustrating an example of a planar structure of an active matrix substrate 100 according to an embodiment.

FIG. 2 is a partial plan view schematically illustrating the active matrix substrate 100 according to the embodiment.

FIG. 3 is a partial cross-sectional view schematically illustrating the active matrix substrate 100, taken along line A-A in FIG. 2.

FIG. 4 is a partial cross-sectional view schematically illustrating the active matrix substrate 100 according to the embodiment, taken along line B-B in FIG. 2.

FIG. 5A is a cross-sectional view illustrating a step for manufacturing the active matrix substrate 100 according to the embodiment.

FIG. 5B is a cross-sectional view illustrating a step for manufacturing the active matrix substrate 100 according to the embodiment.

FIG. 5C is a cross-sectional view illustrating a step for manufacturing the active matrix substrate 100 according to the embodiment.

FIG. 5D is a cross-sectional view illustrating a step for manufacturing the active matrix substrate 100 according to the embodiment.

FIG. 5E is a cross-sectional view illustrating a step for manufacturing the active matrix substrate 100 according to the embodiment.

FIG. 6A is a cross-sectional view illustrating a step for manufacturing the active matrix substrate 100 according to the embodiment.

FIG. 6B is a cross-sectional view illustrating a step for manufacturing the active matrix substrate 100 according to the embodiment.

FIG. 6C is a cross-sectional view illustrating a step for manufacturing the active matrix substrate 100 according to the embodiment.

FIG. 6D is a cross-sectional view illustrating a step for manufacturing the active matrix substrate 100 according to the embodiment.

FIG. 7A is a cross-sectional view illustrating a step for manufacturing the active matrix substrate 100 according to the embodiment.

FIG. 7B is a cross-sectional view illustrating a step for manufacturing the active matrix substrate 100 according to the embodiment.

FIG. 7C is a cross-sectional view illustrating a step for manufacturing the active matrix substrate 100 according to the embodiment.

FIG. 7D is a cross-sectional view illustrating a step for manufacturing the active matrix substrate 100 according to the embodiment.

FIG. 8A is a step cross-sectional view illustrating another step for manufacturing an active matrix substrate 200.

FIG. 8B is a cross-sectional view illustrating a step for manufacturing the active matrix substrate 200 according to another embodiment.

FIG. 9A is a cross-sectional view illustrating a step for manufacturing an active matrix substrate 300 according to still another embodiment.

FIG. 9B is a cross-sectional view illustrating a step for manufacturing the active matrix substrate 300 according to the still another embodiment.

FIG. 9C is a cross-sectional view illustrating a step for manufacturing the active matrix substrate 300 according to the still another embodiment.

FIG. 9D is a cross-sectional view illustrating a step for manufacturing the active matrix substrate 300 according to the still another embodiment.

FIG. 9E is a cross-sectional view illustrating a step for manufacturing the active matrix substrate 300 according to the still another embodiment.

FIG. 10A is a cross-sectional view illustrating a step for manufacturing the active matrix substrate 300 according to the still another embodiment.

FIG. 10B is a cross-sectional view illustrating a step for manufacturing the active matrix substrate 300 according to the still another embodiment.

FIG. 10C is a cross-sectional view illustrating a step for manufacturing the active matrix substrate 300 according to the still another embodiment.

FIG. 10D is a cross-sectional view illustrating a step for manufacturing the active matrix substrate 300 according to the still another embodiment.

FIG. 10E is a cross-sectional view illustrating a step for manufacturing the active matrix substrate 300 according to the still another embodiment.

FIG. 11A is a cross-sectional view illustrating a step for manufacturing an active matrix substrate 400 according to yet another embodiment.

FIG. 11B is a cross-sectional view illustrating a step for manufacturing the active matrix substrate 400 according to the yet another embodiment.

FIG. 12A is a cross-sectional view illustrating a step for manufacturing an active matrix substrate 500 according to a further embodiment.

FIG. 12B is a cross-sectional view illustrating a step for manufacturing the active matrix substrate 500 according to the further embodiment.

FIG. 12C is a cross-sectional view illustrating a step for manufacturing the active matrix substrate 500 according to the further embodiment.

FIG. 13 is a cross-sectional view schematically illustrating a liquid crystal display device 1000 that includes the active matrix substrate 100, (200, 300, 400, or 500) according to an embodiment.

FIG. 14 is a cross-sectional view schematically illustrating an active matrix substrate 900 in Comparative Example.

### DESCRIPTION OF EMBODIMENTS

### First Embodiment

Hereinafter, an active matrix substrate, a liquid crystal display device, and a method for manufacturing an active matrix substrate according to an embodiment will be described with reference to the drawings as appropriate. In the following, an active matrix substrate for use in a liquid crystal display device will be exemplified as an embodiment of the active matrix substrate, but the present technology is not limited thereto.

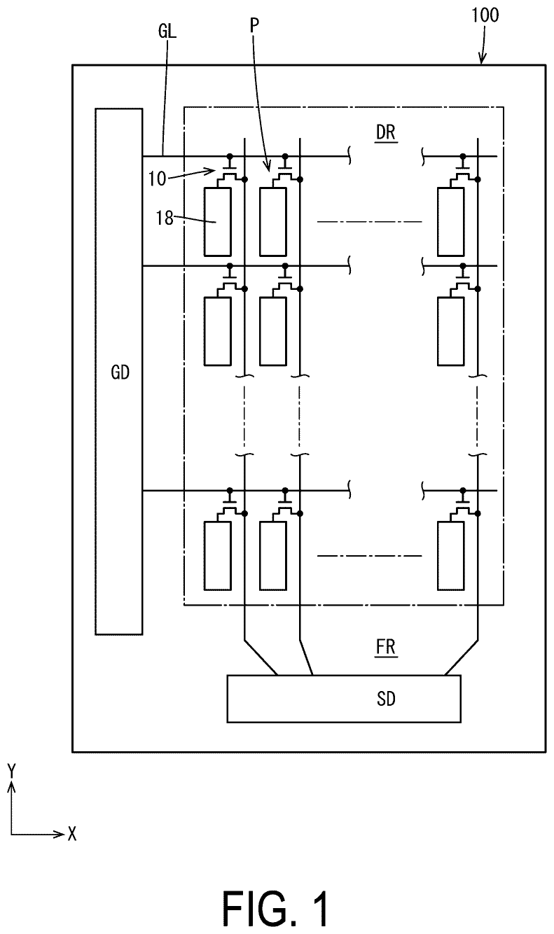

FIG. 1 is a schematic diagram illustrating an example of a planar structure of an active matrix substrate 100 according to the embodiment. Arrows X, Y, and Z in the figures correspond to a row direction and a column direction of the active matrix substrate 100 to be described later, and a normal direction of a substrate 1, respectively.

The active matrix substrate 100 will be outlined. The active matrix substrate 100 has a display region DR and a non-display region (also referred to as a “frame region”) FR. The display region DR is a region for displaying a digital image and includes a plurality of pixel regions P. Each of the plurality of pixel regions P is a region corresponding to one pixel, which is the smallest unit, and a plurality of pixels constitute a digital image. Each of the plurality of pixel regions P is sometimes simply referred to as a “pixel”. The plurality of pixel regions P are arrayed in a matrix shape consisting of a plurality of rows and a plurality of columns. The non-display region FR is a region that does not contribute to display, and is located around the display region DR.

The active matrix substrate 100 is configured by providing on a substrate 1, a large scale integrated circuit (LSI) that constitutes the plurality of pixels. In a portion of the substrate 1 corresponding to the display region DR, a plurality of gate wiring lines GL extending in a row direction and a plurality of source wiring lines SL extending in a column direction are provided. Each pixel region P is, for example, a region surrounded by a pair of gate wiring lines GL adjacent to each other and a pair of source wiring lines SL adjacent to each other.

Peripheral circuits are located in a portion of the substrate 1 corresponding to the non-display region FR. Here, as a peripheral circuit, a gate driver GD that drives the gate wiring lines GL is provided integrally (monolithically) with the substrate 1. Further, as a peripheral circuit, a source driver SD that drives the source wiring lines SL is mounted on the substrate 1. Note that as a peripheral circuit, for example, a source shared driving (SSD) circuit that drives source bus lines (source wiring lines SL) in a time-division manner may be further located, and for example, the SSD circuit may be located integrally with the substrate 1 similarly to the gate driver GD.

In each pixel region P on the substrate 1, a thin film transistor (TFT) 10 and a pixel electrode 18 electrically connected to the TFT 10 are located. The TFT 10 located in each pixel region P may be referred to as a “pixel TFT”. The TFT 10 is supplied with a gate signal (scanning signal) from a corresponding gate wiring line GL and supplied with a source signal (display signal) from a corresponding source wiring line SL. Note that for simplicity, FIG. 1 illustrates one gate wiring line GL for each pixel row. However, as will be described in detail later, a plurality of gate wiring lines GL (e.g., a lower gate wiring line and an upper gate wiring line) may be located for each pixel row, and gate signals may be supplied to each TFT 10 from these lower gate wiring line and upper gate wiring line. In other words, the TFT 10 may be, for example, a so-called double-gate thin film transistor.

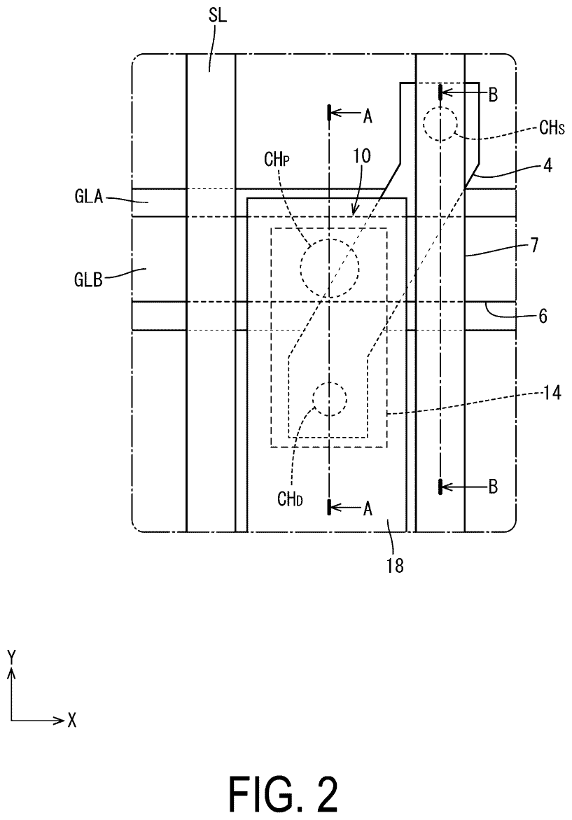

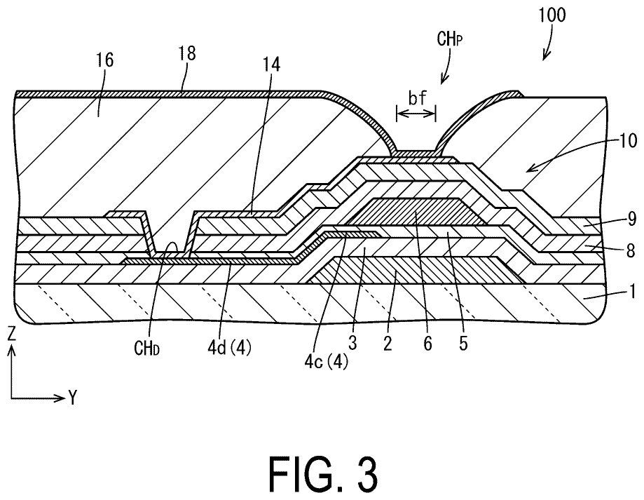

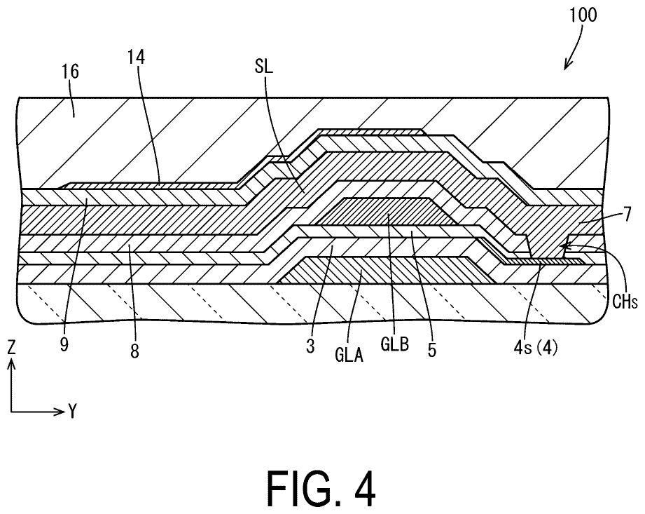

Next, a more specific structure of the active matrix substrate 100 will be described with reference to FIGS. 2 to 4. FIG. 2 is a partial plan view schematically illustrating the active matrix substrate 100, illustrating a region where the gate wiring lines GL and the source wiring lines SL intersect. FIG. 3 is a partial cross-sectional view schematically illustrating the active matrix substrate 100, taken along line A-A in FIG. 2. FIG. 4 is a partial cross-sectional view schematically illustrating the active matrix substrate 100 according to the embodiment, taken along line B-B in FIG. 2.

As illustrated in FIG. 3 and the like, the active matrix substrate 100 includes the substrate 1, the TFTs 10 supported by the substrate 1, insulating layers covering the TFTs 10 (e.g., a first interlayer insulating layer 8 and a second interlayer insulating layer 9), a flattened layer 16 covering these insulating layers, the pixel electrodes 18 located on the flattened layer 16, and connection electrodes 14 located between the insulating layer (e.g., the second interlayer insulating layer 9) and the flattened layer 16.

The substrate 1 has insulating properties. For example, the substrate 1 for use in a liquid crystal display device is transparent and typically a glass substrate or a transparent plastic substrate. In the present technology, “transparent” refers to transparent to visible light (e.g., transmittance of 80% or more, preferably 90% or more, more preferably 95% or more, and still more preferably 99% or more).

The TFT 10 is located in each pixel region P on the substrate 1. The TFT 10 includes a lower gate electrode 2, a lower gate insulating layer 3, an oxide semiconductor layer 4, an upper gate insulating layer 5, an upper gate electrode 6, and a source electrode 7.

The lower gate electrode 2 is located on, for example, the substrate 1. The lower gate electrode 2 is electrically connected to a corresponding lower gate wiring line GLA. In the illustrated example, a portion of the lower gate wiring line GLA (to be specific, a portion facing the oxide semiconductor layer 4) functions as the lower gate electrode 2. In this specification, the lower gate electrode 2 and a wiring line and/or an electrode formed in the same layer as this lower gate electrode 2 (by patterning the same conductive film) are collectively referred to as a “lower gate metal layer”. Here, the lower gate metal layer includes the lower gate electrode 2 and the lower gate wiring line GLA.

The lower gate insulating layer 3 covers the lower gate electrode 2. The lower gate insulating layer 3 insulates the lower gate electrode 2 from a conductive layer above the lower gate electrode 2 (here, the oxide semiconductor layer 4).

The oxide semiconductor layer 4 is located on the lower gate insulating layer 3. The oxide semiconductor layer 4 has a channel region 4c facing the lower gate electrode 2 with the lower gate insulating layer 3 interposed therebetween, a source region 4s positioned on one side of the channel region 4c, and a drain region 4d positioned on another side of the channel region 4c. The source region 4s and the drain region 4d of the oxide semiconductor layer 4 are regions that have been made conductive by, for example, a resistance reduction process described later.

The upper gate insulating layer 5 is located at least on the channel region 4c of the oxide semiconductor layer 4. The upper gate insulating layer 5 insulates the upper gate electrode 6 from a conductive layer below the upper gate electrode 6 (here, the oxide semiconductor layer 4). Here, the upper gate insulating layer 5 is located so as to cover the entire oxide semiconductor layer 4.

The upper gate electrode 6 is located on the upper gate insulating layer 5 and faces the channel region 4c of the oxide semiconductor layer 4 with the upper gate insulating layer 5 interposed therebetween. The upper gate electrode 6 is electrically connected to a corresponding upper gate wiring line GLB. In the illustrated example, a portion of the upper gate wiring line GLB (to be specific, a portion facing the oxide semiconductor layer 4) functions as the upper gate electrode 6. In this specification, the upper gate electrode 6 and a wiring line and/or an electrode formed in the same layer as the upper gate electrode 6 (by patterning the same conductive film) are collectively referred to as an “upper gate metal layer”. Here, the upper gate metal layer includes the upper gate electrode 6 and the upper gate wiring line GLB. The upper gate electrode 6 may be given the same potential as the lower gate electrode 2, or may be given a different potential, for example, for threshold control. When the same potential is applied to the upper gate electrode 6 and the lower gate electrode 2, the upper gate wiring line GLB and the lower gate wiring line GLA may be electrically connected. When the same potential is applied to the upper gate electrode 6 and the lower gate electrode 2, one of the upper gate electrode 6 and the lower gate electrode 2 may be an island-shaped electrode electrically connected to the other.

The first interlayer insulating layer 8 is located so as to cover the upper gate electrode 6 and the oxide semiconductor layer 4. The source electrode 7 is located on the first interlayer insulating layer 8. In the first interlayer insulating layer 8, a source contact hole CHs is formed so that a portion of the source region 4s of the oxide semiconductor layer 4 is exposed. The source electrode 7 is in contact with the source region 4s in the source contact hole, and is electrically connected to the source region 4s. The source electrode 7 is electrically connected to a corresponding source wiring line SL. In the illustrated example, a portion of the source wiring line SL (to be specific, a portion facing the oxide semiconductor layer 4) functions as the source electrode 7. In this specification, the source electrode 7 and a wiring line and/or an electrode formed in the same layer as the source electrode 7 (by patterning the same conductive film) are collectively referred to as a “source metal layer”. Here, the source metal layer includes the source electrode 7 and the source wiring line SL.

The second interlayer insulating layer 9 is located so as to cover the TFT 10, and the flattened layer 16 is formed on the second interlayer insulating layer 9. The flattened layer 16 is made of, for example, an organic insulating material. The flattened layer 16 in the present technology is made of typically a transparent organic insulating material. The flattened layer 16 is made of, for example, a photosensitive resin. The pixel electrode 18 is located on the flattened layer 16. The pixel electrode 18 is electrically connected to the TFT 10.

The exemplified active matrix substrate 100 is used in a fringe field switching (FFS) mode liquid crystal display device, and further includes a dielectric layer located so as to cover the pixel electrodes 18, and a common electrode located on the dielectric layer and facing the pixel electrodes 18, although these are not illustrated here. At least one slit is formed in the common electrode for each pixel region P.

The active matrix substrate 100 further includes the connection electrodes 14, each of which electrically connects the drain region 4d of the oxide semiconductor layer 4 and the pixel electrode 18. The connection electrodes 14 are located between the second interlayer insulating layer 9 and the flattened layer 16. The connection electrodes 14 are formed from a transparent conductive material. In the first interlayer insulating layer 8 and the second interlayer insulating layer 9, a drain contact hole CH_{D} is formed so that a portion of the drain region 4d of the oxide semiconductor layer 4 is exposed. A portion of the connection electrode 14 is in contact with the drain region 4d in the drain contact hole CH_{D}.

The flattened layer 16 has a pixel contact hole CH_{P} formed so that a portion of the connection electrode 14 is exposed. A portion of the pixel electrode 18 is in contact with the connection electrode 14 in the pixel contact hole CH_{D}. Here, when viewed from the normal direction of the substrate 1, a bottom face bf of the pixel contact hole CH_{D} is positioned so as to at least partially overlap both the lower gate metal layer and the upper gate metal layer. To be more specific, the bottom face bf of the pixel contact hole CH_{D} overlaps, at least partially, both the lower gate electrode 2 and the upper gate electrode 6. In the example illustrated in FIG. 3, the bottom face bf of the pixel contact hole CH_{D} as a whole overlaps both the lower gate metal layer and the upper gate metal layer, to be more specific, both the lower gate electrode 2 and the upper gate electrode 6.

With such a configuration, the active matrix substrate 100 can improve transmittance compared to, for example, an active matrix substrate 900 in Comparative Example. This point will be described below.

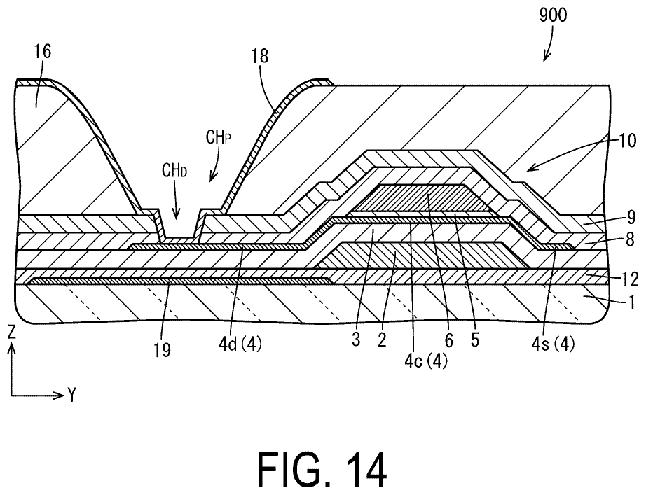

FIG. 14 is a cross-sectional view schematically illustrating the active matrix substrate 900 in Comparative Example.

The active matrix substrate 900 in Comparative Example includes the TFTs 10 having a double gate structure. However, in the active matrix substrate 900 in Comparative Example, when viewed from the normal direction of the substrate 1, the pixel contact hole CH_{P} formed in the flattened layer 16 overlaps neither the lower gate electrode 2 nor the upper gate electrode 6 but overlaps the drain region 4d of the oxide semiconductor layer 4. The pixel contact hole CH_{P} is located, when viewed from the normal direction of the substrate 1, at a position overlapping the drain contact hole CH_{D} formed in the first interlayer insulating layer 8 and the second interlayer insulating layer 9 (to be more specific, so that the pixel contact hole CH_{D} is positioned in the drain contact hole CH_{D}). A portion of the pixel electrode 18 is in direct contact with the drain region 4d of the oxide semiconductor layer 4 in the drain contact hole CH_{D}, and thus the pixel electrode 18 is electrically connected to the oxide semiconductor layer 4. Therefore, the active matrix substrate 900 in Comparative Example does not include the connection electrode 14.

The active matrix substrate 900 in Comparative Example includes a light blocking layer 19 located so as to overlap the pixel contact hole CH_{D} when viewed from the normal direction of the substrate 1. The light blocking layer 19 is formed on the substrate 1 and formed of a metal film having low light transmittance, so that a base coat layer 12 is required to cover the light blocking layer 19. Thus, the TFT 10 is located on the base coat layer 12.

In such an active matrix substrate 900 in Comparative Example, in order to reliably electrically connect the pixel electrode 18 and the oxide semiconductor layer 4, the drain contact hole CH_{D} and the pixel contact hole CH_{D} need to be formed so as to overlap each other. However, when positions of the drain contact hole CH_{D} and the pixel contact hole CH_{D} are too close, the photosensitive resin material constituting the flattened layer 16 may remain at a bottom of the drain contact hole CH_{D}, which may result in poor conductivity. Therefore, an opening diameter of the pixel contact hole CH_{D} needs to be sufficiently large relative to an opening diameter of the drain contact hole CH_{D}, and thus an exposure time when forming the pixel contact hole CH_{P} needs to be set to be sufficiently long. Accordingly, the pixel contact hole CH_{D} has a gentle cone shape having a tapered side surface that spreads from the bottom face of the pixel contact hole CH_{D}. Thus, it is difficult to reduce the opening diameter of the pixel contact hole CH_{D} relative to the opening diameter of the drain contact hole CH_{D}. When used in a liquid crystal display device, the pixel contact hole CH_{P} having such a shape disturbs alignment of liquid crystal molecules, which causes a decrease in a contrast ratio and display quality due to light leakage in the liquid crystal display device. Therefore, it is necessary to block light from reaching the vicinity of the pixel contact hole CH_{D} by the light blocking layer 19 of the active matrix substrate 900 and a black matrix located on a counter substrate. However, in that case, light from a backlight is blocked by the light blocking layer 19 and the black matrix, resulting in a decrease in transmittance.

As already described, JP 2017-187714 A discloses a configuration that can make a contact hole formed in a flattened layer (organic insulating film) shallower. In the configuration disclosed in JP 2017-187714 A, an electrode (metal portion) that electrically connects a polysilicon semiconductor layer, which is an active layer of a TFT, and a pixel electrode is raised by a pedestal portion located directly under the electrode, whereby a contact hole formed in a flattened layer can be made shallower.

However, when a complicated structure such as that disclosed in JP 2017-187714 A is actually formed in a pixel, light leakage is a concern. For example, a phenomenon in which an edge of the metal portion formed in an island shape shines (striation phenomenon) may occur. In order to prevent light leakage due to such a striation phenomenon, it is considered necessary to block the light from reaching the vicinity of the metal portion (the vicinity of the pedestal portion) by the light blocking layer of the active matrix substrate and the black matrix of the counter substrate. Therefore, when the configuration disclosed in JP 2017-187714 A is employed, although the contact hole can be formed to be shallow, it is difficult to significantly improve transmittance (significantly improve aperture ratio).

In contrast, in the active matrix substrate 100 according to the present embodiment, when viewed from the normal direction of the substrate 1, the bottom face bf of the pixel contact hole CH_{D} overlaps, at least partially, both the lower gate electrode 2 and the upper gate electrode 6. Thus, when the photosensitive resin material is exposed, a thickness of the photosensitive resin material in the region where the pixel contact hole CH_{D} is formed is reduced by thicknesses of the lower gate electrode 2 and the upper gate electrode 6, and the exposure light is reflected by the lower gate electrode 2 and/or the upper gate electrode 6, so that the pixel contact hole CH_{P} can be formed with a shorter exposure time and a smaller mask pattern. Therefore, the opening diameter of the pixel contact hole CH_{D} can be reduced. Since the opening diameter of the pixel contact hole CH_{D} can be reduced, the lower gate electrode 2 and the upper gate electrode 6 can sufficiently block light without forming a light blocking layer, thereby improving transmittance. In the active matrix substrate 100 according to the present embodiment, it is not necessary to separately form a structure such as the pedestal portion disclosed in JP 2017-187714 A.

In the active matrix substrate 100 according to the present embodiment, the connection electrode 14 for electrically connecting the drain region 4d of the oxide semiconductor layer 4 and the pixel electrode 18 is made of a transparent conductive material. Therefore, a periphery of the drain region 4d (a periphery of the drain contact hole CH_{D}) can be made to contribute to the display, and the aperture ratio can be increased to further improve transmittance.

Note that here, according to investigations of the inventors, a value of contact resistance between the oxide semiconductor layer 4 and the connection electrode 14 made of a transparent conductive material (e.g., ITO or IZO) can be higher than a value of contact resistance when the connection electrode is made of, for example, a metal material. For example, a value of contact resistance between the connection electrode 14 (e.g., ITO) and the oxide semiconductor layer 4 (e.g., In—Ga—Zn—O-based oxide semiconductor) in the drain contact hole CH_{D} may be several tens of times higher than a value of contact resistance between the oxide semiconductor layer 4 and the source electrode 7 (e.g., layered film of Ti/Al/Ti) in the source contact hole CHs. This is due to the following reasons.

First, the oxide semiconductor layer 4 has high ionic bonding properties, and is easily oxidized by adsorbing water vapor or oxygen molecules on a surface of the oxide semiconductor layer 4. Therefore, when the first interlayer insulating layer 8 and the second interlayer insulating layer 9 are etched in forming the drain contact hole CH_{D} and the source contact hole CHs, the surface of the exposed oxide semiconductor layer 4 below is oxidized (excessively stabilized). Here, even when the oxide semiconductor layer 4 has an oxidized surface, when the oxide semiconductor layer 4 is in contact with the source electrode 7 made of a metal material, oxygen on the surface of the oxide semiconductor layer 4 moves to the source electrode 7 due to an oxidation-reduction reaction at an interface, and thus oxygen is reduced from the surface of the oxide semiconductor layer 4. Therefore, on the surface of the oxide semiconductor layer 4 exposed through the source contact hole CHs, carriers increase and the contact resistance is reduced.

In contrast, when a transparent conductive material (e.g., ITO) is used for the connection electrode 14, oxygen is further supplied to the oxide semiconductor layer 4 when forming the connection electrode 14. This reduces carriers (e.g., oxygen defects) that contribute to electrical conduction on the surface of the oxide semiconductor layer 4, and the contact resistance becomes even higher.

In order to reduce the resistance at the contact portion with such an oxide semiconductor layer 4, it is conceivable to increase an amount of impurities doped during a resistance reduction process of the oxide semiconductor layer 4. However, simply increasing the amount of impurities doped in the oxide semiconductor layer 4 increases overall mobility in the source region 4s and the drain region 4d. In this case, transistor characteristics such as a threshold voltage of the TFT 10 may change, which may cause a new problem that desired characteristics cannot be obtained.

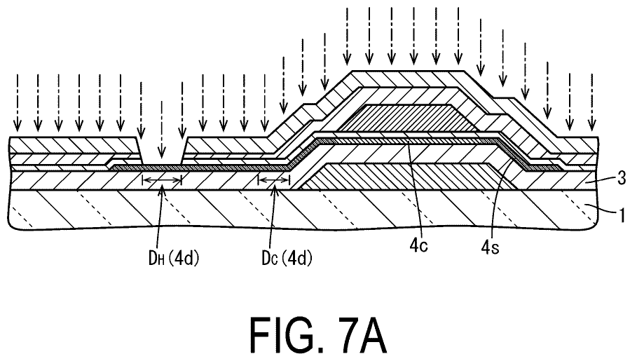

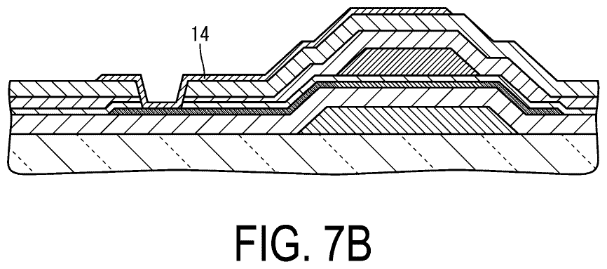

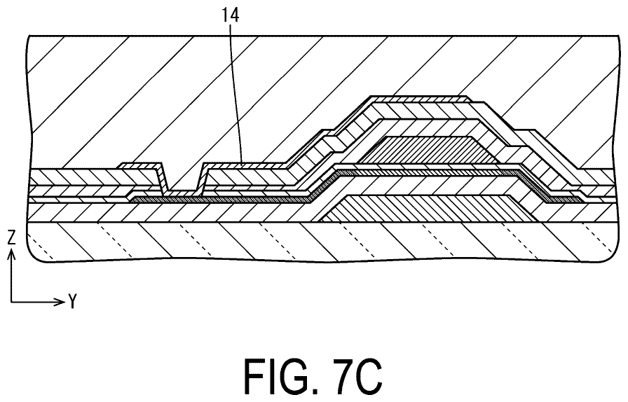

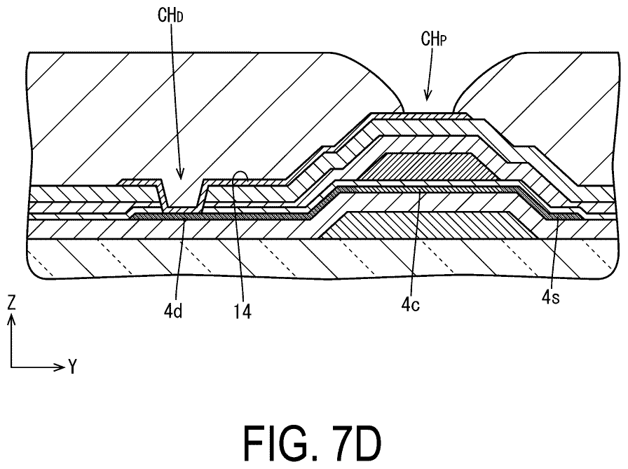

Therefore, in the present technology, the drain region 4d is configured so that an impurity concentration in a portion D_{H} overlapping the drain contact hole CH_{D} is higher than an impurity concentration of at least a portion adjacent to the channel region 4c (see FIG. 7A). The portion D_{H} overlapping the drain contact hole CH_{D} refers to a region of the drain region 4d that overlaps the drain contact hole CH_{D} when viewed from the normal direction of the substrate 1. The impurity concentration in the portion D_{H} does not necessarily have to be uniform. It is sufficient that the impurity concentration in the portion D_{H} as a whole is higher than the impurity concentration of the other regions of the drain region 4d. It is sufficient that an impurity concentration M₁ of the portion D_{H} of the drain region 4d that overlaps the drain contact hole CH_{D} is higher than, for example, an impurity concentration M₂ of a portion Dc of the drain region 4d that is adjacent to the channel region 4c. Note that the portion Dc adjacent to the channel region 4c means a region between the portion D_{H} of the drain region 4d and the channel region 4c. However, for example, as illustrated in FIG. 7A, a region that is a portion of a region between this portion D_{H} and the channel region 4c, and has an impurity concentration, which is an average impurity concentration of this region, can be regarded as a representative of the portion Dc adjacent to the channel region 4c.

As the impurities, various elements that can act as donors or acceptors in the target oxide semiconductor layer 4 can be considered. Examples of the various elements include group 13 elements represented by boron (B), aluminum (Al), gallium (Ga), and indium (In), and group 15 elements represented by phosphorus (P), arsenic (As), and antimony (Sb). Hydrogen (H) may be used as the impurity.

By making the impurity concentration M₁ of the portion D_{H} overlapping the drain contact hole CH_{D}, for example, slightly higher than the impurity concentration M₂ of the portion Dc adjacent to the channel region 4c, an effect of reducing the contact resistance with the connection electrode 14 can be obtained. The impurity concentration M₁ of the portions D_{H} overlapping the drain contact hole CH_{D} can be set to a concentration sufficient to achieve a desired contact between the connection electrode 14 and the drain region 4d (and further the source electrode 7). Although it depends on etching conditions and a configuration of the oxide semiconductor layer 4 and the like, for example, in order to suitably reduce the contact resistance, it is exemplified that the impurity concentration M₁ of the portion D_{H} overlapping the drain contact hole CH_{D} is higher than the impurity concentration M₂ of the portion Dc adjacent to the channel region 4c by about 10¹³ ions/cm² to 10¹⁶ ions/cm², for example, about 10¹³ to 10¹⁵ ions/cm² in terms of dose amount.

As will be described later, when impurity doping is performed in a resistance reduction process of the oxide semiconductor layer 4, the impurity concentration M₁ of the portion D_{H} is higher than the impurity concentration M₂ of the portion Dc by an amount corresponding to the dose amount described above. When the same impurity ions are used in the resistance reduction process of the oxide semiconductor layer 4 and the resistance reduction process of the portion D_{H}, the amount of the impurity ions is larger in the portion D_{H} than the amount in the portion Dc by an amount corresponding to the dose amount described above. When different impurity ions are used in the resistance reduction process of the oxide semiconductor layer 4 and the resistance reduction process of the portion D_{H}, the portion D_{H} contains impurity ions that are not contained in the portion Dc by the dose amount described above. When a method other than impurity doping (e.g., plasma process) is employed in the resistance reduction process of the oxide semiconductor layer 4, the portion D_{H} contains impurity ions that are not contained in the portion Dc by an amount corresponding to the dose amount described above. Such impurity concentrations in the portion D_{H} overlapping the drain contact hole CH_{D} and the portion Dc adjacent to the channel region 4c can be confirmed by, for example, performing a structural analysis on cross sections of these portions of the drain region 4d.

The method of confirming the impurity concentrations is not limited to any particular method. For example, various methods can be employed that can evaluate a relative concentration of impurities between the portion D_{H} overlapping the drain contact hole CH_{D} and the portion Dc adjacent to the channel region 4c. One example is to measure the impurity concentrations in a depth direction in a cross section perpendicular to the substrate by time-of-flight secondary ion mass spectrometry (TOF-SIMS). The concentration may be a surface density (ions/cm² or atoms/cm²) or a volume density (ions/cm³ or atoms/cm³). Another example is the use of energy dispersive X-ray spectroscopy (EDX) to perform qualitative and quantitative analysis of elements in a predetermined region of a surface (including a plane substantially parallel to or perpendicular to a substrate, a milled surface, etc.). In addition, the impurity concentration may be evaluated by cross-sectional structure analysis (e.g., dopant contrast analysis) using a focused ion beam (FIB) and a scanning electron microscope (SEM), or the like, an atomic force microscope (AFM), or a scanning microwave microscope (SMM).

### Manufacturing Method 1: Activation of Oxide Semiconductor Layer by Impurity Doping 1

A method for increasing the impurity concentration of the portion D_{H} overlapping the drain contact hole CH_{D}, that is, a method for manufacturing the active matrix substrate 100 in the present embodiment, will be described.

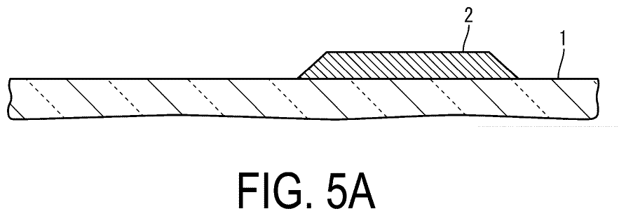

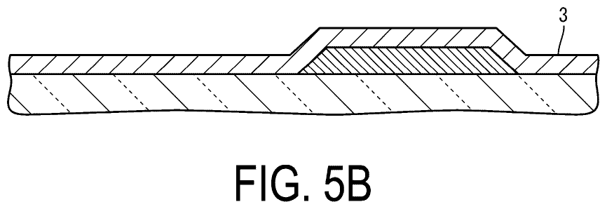

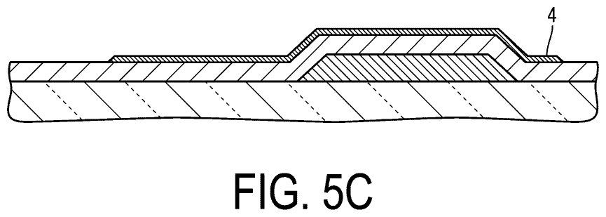

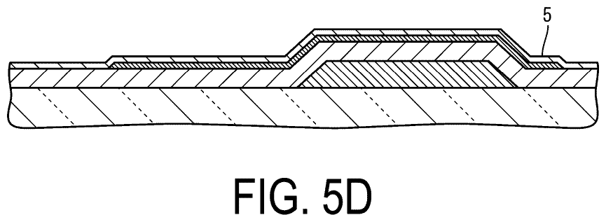

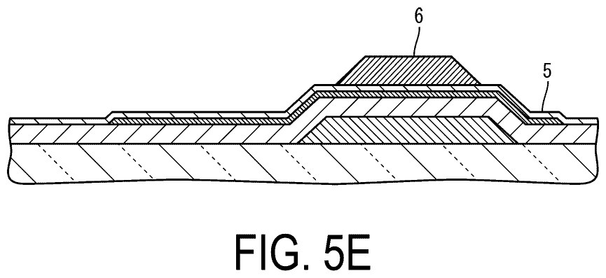

FIGS. 5A to 7D are step cross-sectional views illustrating steps for manufacturing the active matrix substrate 100.

First, as illustrated in FIG. 5A, the lower gate electrode 2 and the lower gate wiring line GLA (i.e. the lower gate metal layer) are formed on the substrate 1. For example, a conductive film is deposited by sputtering, and then the conductive film is patterned by a photolithography process, thereby forming the lower gate electrode 2 and the lower gate wiring line GLA.

For example, a glass substrate, a silicon substrate, a plastic substrate (resin substrate) having heat resistance, or the like can be used as the substrate 1. Examples of materials constituting the lower gate metal layer include metals such as aluminum (Al), tungsten (W), molybdenum (Mo), tantalum (Ta), chromium (Cr), titanium (Ti), and copper (Cu), and alloys thereof, and metal nitrides thereof. The lower gate metal layer may be a layered film in which films made of a plurality of these materials are laminated. Here, a film in which a tantalum nitride (TaN) film and a W film are layered in this order is used as the lower gate metal layer. A thickness of the lower gate metal layer is, for example, 100 nm or more and 500 nm or less.

Subsequently, as illustrated in FIG. 5B, the lower gate insulating layer 3 is formed so as to cover the lower gate electrode 2 and the lower gate wiring line GLA. For example, the lower gate insulating layer 3 can be formed by CVD. Examples of materials constituting the lower gate insulating layer 3 include silicon oxide (SiO₂), silicon nitride (SiNx), silicon oxynitride (SiOxNy; x>y), and silicon nitride oxide (SiNxOy; x>y). The lower gate insulating layer 3 may have a layered structure. For example, a silicon nitride layer for preventing diffusion of impurities and the like from the substrate 1 may be formed as a lower layer on the substrate 1 side, and a silicon oxide layer for ensuring insulating properties may be formed on top of the silicon nitride layer as an upper layer. A thickness of the lower gate insulating layer 3 is 150 nm or more and 400 nm or less.

Subsequently, as illustrated in FIG. 5C, the oxide semiconductor layer 4 is formed on the lower gate insulating layer 3. For example, an oxide semiconductor film is deposited by sputtering, and then the oxide semiconductor film is patterned by a photolithography process to form the island-shaped oxide semiconductor layer 4. Note that at this stage, the source region 4s and the drain region 4d are not yet formed. The oxide semiconductor layer 4 is formed so as to face the lower gate electrode 2 with the lower gate insulating layer 3 interposed therebetween. As a material constituting the oxide semiconductor layer 4, various oxide semiconductor materials can be considered. Here, as the oxide semiconductor layer 4, an In—Ga—Zn—O based semiconductor layer having a composition ratio of In:Ga:Zn=1:1:1 is formed. A thickness of the oxide semiconductor layer 4 is, for example, 10 nm or more and 200 nm or less.

Subsequently, as illustrated in FIG. 5D, the upper gate insulating layer 5 is deposited so as to cover the oxide semiconductor layer 4. The upper gate insulating layer 5 is deposited, for example, by CVD. Thereafter, the oxide semiconductor layer 4 is subjected to an oxidation treatment (e.g., baking or peroxide treatment). As the upper gate insulating layer 5, for example, an insulating layer similar to the lower gate insulating layer 3 (exemplified as the lower gate insulating layer 3) can be used. Here, as the upper gate insulating layer 5, a silicon oxide (e.g., SiO₂) layer is formed. When an oxide layer such as a silicon oxide layer is used as the upper gate insulating layer 5, oxygen deficiencies generated in the channel region 4c of the oxide semiconductor layer 4 can be reduced by the oxide layer, so that a decrease in resistance of the channel region can be suppressed. A thickness of the upper gate insulating layer 5 is, for example, 50 nm or more and 150 nm or less.

Subsequently, as illustrated in FIG. 5E, the upper gate electrode 6 and the upper gate wiring line GLB (i.e., the upper gate metal layer) are formed on the upper gate insulating layer 5. For example, a conductive film (upper gate metal film) is deposited by sputtering, and then the upper gate metal film is patterned by a photolithography process, thereby forming the upper gate electrode 6 and the upper gate wiring line GLB. As the upper gate metal film, for example, a film containing a metal such as aluminum (Al), tungsten (W), molybdenum (Mo), tantalum (Ta), chromium (Cr), titanium (Ti), or copper (Cu), or an alloy thereof, or a metal nitride thereof, can be used. Here, a film in which a Ti film, an Al film, and a Ti film are layered in this order is used as the upper gate metal film. A thickness of the upper gate metal film is, for example, 100 nm or more and 400 nm or less.

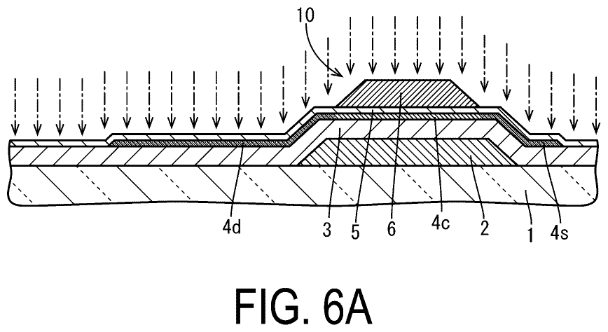

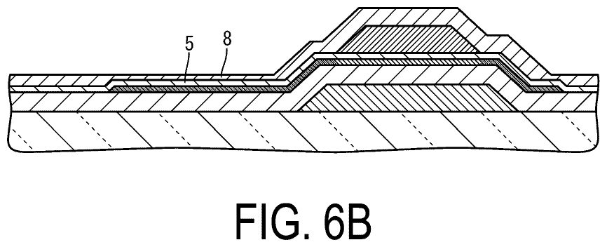

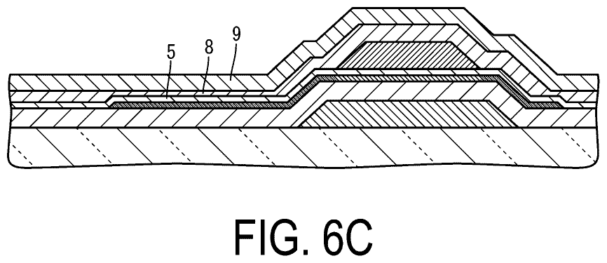

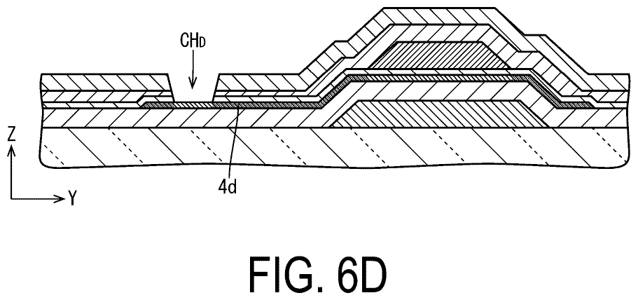

Thereafter, as illustrated in FIG. 6A, a resistance reduction process is performed on the oxide semiconductor layer 4. Here, impurities are doped into the oxide semiconductor layer 4 from above the upper gate insulating layer 5 using the upper gate electrode 6 as a mask. By doping with the impurities, regions of the oxide semiconductor layer 4 that do not overlap the upper gate electrode 6 (regions that become the source region 4s and the drain region 4d) become low-resistive regions having a lower specific resistance than a resistance of a region of the oxide semiconductor layer 4 that overlaps the upper gate electrode 6 (a region that becomes the channel region 4c). The low-resistive region may be a conductive region (for example, sheet resistance equal to or less than 200Ω/□).

As the impurity, for example, at least one of the above-described group 13 elements and group 15 elements can be used. Here, for example, phosphorus (P) is used as the impurity. For example, impurities such as phosphorus (P) are prepared as an ion source gas or the like such as phosphine (PH₃), ionized by applying plasma energy or the like, and accelerated by applying an electromagnetic field to be injected into the oxide semiconductor layer 4. Thus, the impurities are injected into regions of the oxide semiconductor layer 4 that are not covered with the upper gate electrode 6, forming the source region 4s and the drain region 4d. A region of the oxide semiconductor layer 4 that is covered with the upper gate electrode 6 is not injected with impurities and serves as the channel region 4c. The channel region 4c is located between the source region 4s and the drain region 4d and separates the two regions. Although not limited thereto, an amount of impurities injected to form the source region 4s and the drain region 4d is exemplified to be, for example, about 10¹³ to 10¹⁵ ions/cm².

Subsequently, as illustrated in FIG. 6B, the first interlayer insulating layer 8 is formed to cover the upper gate insulating layer 5 and the upper gate electrode 6. The first interlayer insulating layer 8 can be formed, for example, by CVD. Examples of materials constituting the first interlayer insulating layer 8 include inorganic insulating materials such as silicon oxide (SiO₂), silicon nitride (SiNx), silicon oxynitride (SiOxNy; x>y), and silicon nitride oxide (SiNxOy; x>y). The first interlayer insulating layer 8 can be configured as a single-layer film made of any one material or as a layered film made of two or more materials. A thickness of the first interlayer insulating layer 8 is, for example, 200 nm or more and 700 nm or less. Here, a silicon oxide layer is used as the first interlayer insulating layer 8.

Subsequently, the source contact hole CHs is formed in the first interlayer insulating layer 8 so that a portion of the source region 4s of the oxide semiconductor layer 4 is exposed (see FIG. 4). The source contact hole CHs can be formed, for example, by patterning the first interlayer insulating layer 8 by a photolithography process.

Subsequently, the source electrode 7 and the source wiring line SL (i.e., the source metal layer) are formed on the first interlayer insulating layer 8 (see FIG. 4). For example, a conductive film is deposited by sputtering, and then the conductive film is patterned by a photolithography process, thereby forming the source electrode 7 and the source wiring line SL. Examples of materials constituting the source metal layer include metals such as aluminum (Al), tungsten (W), molybdenum (Mo), tantalum (Ta), copper (Cu), chromium (Cr), and titanium (Ti), and alloys thereof, and metal nitrides thereof. The source metal layer may be configured as a single-layer film made of any of these materials or as a layered film made of two or more materials. Here, a film in which a Ti film, an Al film, and a Ti film are layered in this order is used as the source metal layer. A thickness of the source metal layer is, for example, 200 nm or more and 700 nm or less.

Subsequently, as illustrated in FIG. 6C, the second interlayer insulating layer 9 is formed to cover the TFT 10. For example, the second interlayer insulating layer 9 can be formed by CVD. Examples of materials constituting the second interlayer insulating layer 9 include inorganic insulating materials such as silicon oxide (SiO₂), silicon nitride (SiNx), silicon oxynitride (SiOxNy; x>y), and silicon nitride oxide (SiNxOy; x>y). The second interlayer insulating layer 9 can be configured as a single-layer film made of any one material or a layered film made of two or more materials. A thickness of the second interlayer insulating layer 9 is, for example, 100 nm or more and 600 nm or less. Here, a silicon nitride layer is used as the second interlayer insulating layer 9.

Subsequently, as illustrated in FIG. 6D, the drain contact hole CH_{D} is formed in the first interlayer insulating layer 8 and the second interlayer insulating layer 9 so that a portion of the drain region 4d of the oxide semiconductor layer 4 is exposed. The drain contact hole CH_{D} can be formed, for example, by patterning the first interlayer insulating layer 8 and the second interlayer insulating layer 9 by a photolithography process. The drain contact hole CH_{D} can be formed to have a size of, for example, 1.5 μm to 2.5 μm square. By etching the first interlayer insulating layer 8 and the second interlayer insulating layer 9 in this photolithography process, for example, a surface of the portion of the drain region 4d of the oxide semiconductor layer 4 exposed through the drain contact hole CH_{D} is oxidized.

Therefore, as illustrated in FIG. 7A, in the substrate 1 with the drain contact hole CH_{D} has been formed, impurities are doped from above the second interlayer insulating layer 9. As the impurities, similarly to the step of activating the oxide semiconductor layer 4, impurities that act as donors or acceptors can be employed. The impurities may be the same as or different from the impurities used in the step of activating the oxide semiconductor layer 4. The doping of the impurities can be performed in a manner similar to that in the step of activating the oxide semiconductor layer 4.

Here, the first interlayer insulating layer 8 and the second interlayer insulating layer 9 are sufficiently thick compared to, for example, the upper gate insulating layer 5. Therefore, the impurity ions injected from above the second interlayer insulating layer 9 do not reach a portion of the oxide semiconductor layer 4 that is covered with the first interlayer insulating layer 8 and the second interlayer insulating layer 9. Then, the portion D_{H} of the oxide semiconductor layer 4 exposed through the drain contact hole CH_{D} is doped with the impurities. Thus, the impurity concentration can be selectively increased in the portion D_{H} of the drain region 4d that overlaps the drain contact hole CH_{D}. Also, the contact resistance of the portion D_{H} of the oxide semiconductor layer 4 that is exposed through the drain contact hole CH_{D} and oxidized is reduced. Although not limited thereto, an amount of the impurities injected to reduce the resistance of the portion D_{H} is exemplified to be, for example, about 10¹³ to 10¹⁵ ions/cm². It is understood that those skilled in the art having access to the disclosure will be able to ascertain an amount of impurities suitable for the contact through several trials.

Subsequently, as illustrated in FIG. 7B, the connection electrode 14 is formed on the second interlayer insulating layer 9. For example, a transparent conductive film is deposited by sputtering, and then the transparent conductive film is patterned by a photolithography process, thereby forming the connection electrode 14. As a transparent conductive material for forming the connection electrode 14, for example, indium tin oxide (ITO) or indium zinc oxide (IZO) can be used. Here, indium tin oxide is used. A thickness of the connection electrode 14 is, for example, 30 nm or more and 100 nm or less.

Subsequently, as illustrated in FIG. 7C, the flattened layer 16 is formed to cover the second interlayer insulating layer 9 and the connection electrode 14. The flattened layer 16 can be formed by, for example, applying a photosensitive resin material on the second interlayer insulating layer 9 and the connection electrode 14. Examples of photosensitive resin materials include acrylic resins, silicone resins, epoxy resins, and polyimide resins, which have photosensitivity. Here, a photosensitive acrylic resin is used. A thickness t of the flattened layer 16 is, for example, about 2.5 μm to 5.0 μm.

As illustrated in FIG. 7D, the flattened layer 16 is exposed and developed to remove a portion corresponding to the pixel contact hole CH_{P}, thereby exposing a portion of the connection electrode 14. When a thickness of each of the lower gate electrode 2 and the upper gate electrode 6 is about 300 nm, a depth d of the pixel contact hole CH_{D} is, for example, about 2.2 μm. The pixel contact hole CH_{P} is formed to have, for example, a size of 2.5 μm to 3.5 μm square (may be circular).

Subsequently, as illustrated in FIG. 3, the pixel electrode 18 is formed on the flattened layer 16. For example, a transparent conductive film is deposited by sputtering, and then the transparent conductive film is patterned by a photolithography process, thereby forming the pixel electrode 18. As a transparent conductive material for forming the pixel electrode 18, for example, indium tin oxide or indium zinc oxide can be used. Here, indium zinc oxide is used. A thickness of the pixel electrode 18 is, for example, 30 nm or more and 100 nm or less.

Although not specifically illustrated, for example, the dielectric layer that covers the pixel electrode 18 is then formed. For example, the dielectric layer can be formed by CVD. As the dielectric layer, for example, an inorganic insulating layer similar to the first interlayer insulating layer 8 and the second interlayer insulating layer 9 can be used. Here, a silicon nitride layer is used as the dielectric layer. A thickness of the dielectric layer is, for example, 50 nm or more and 300 nm or less.

Thereafter, the common electrode is formed on the dielectric layer. For example, a transparent conductive film is deposited by sputtering, and then the transparent conductive film is patterned by a photolithography process, thereby forming the common electrode. As a transparent conductive material for forming the common electrode, for example, indium tin oxide or indium zinc oxide can be used. Here, indium zinc oxide is used. A thickness of the common electrode is, for example, 30 nm or more and 100 nm or less. In this manner, the active matrix substrate 100 can be manufactured.

Note that, when a pixel pitch is large enough to provide sufficient space between the source electrode 7 and the connection electrode 14, the connection electrode 14 may be located in the same layer as the source electrode 7 (i.e., on the first interlayer insulating layer 8). In that case, the second interlayer insulating layer 9 can be omitted to simplify the manufacturing process.

### Second Embodiment

### Manufacturing Method 2: Activation of Oxide Semiconductor Layer by Impurity Doping 2

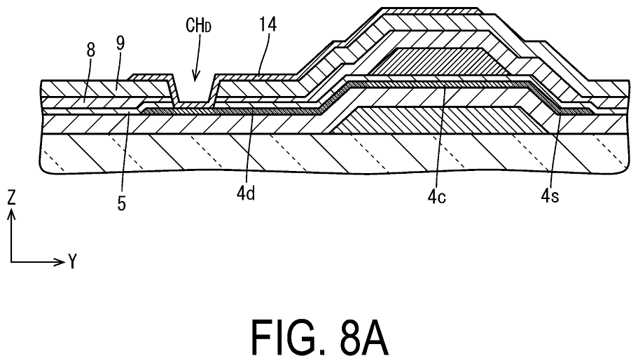

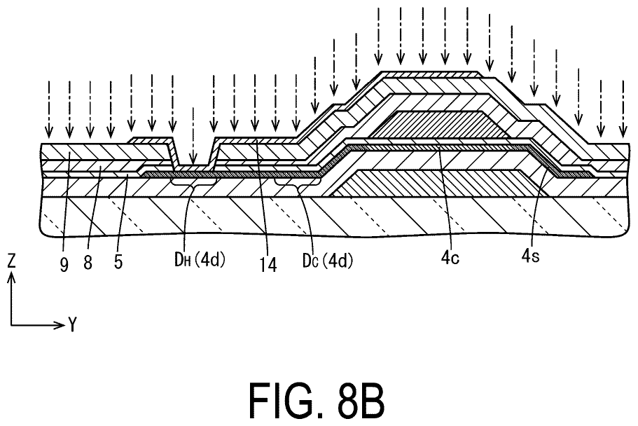

Another method for manufacturing an active matrix substrate 200 according to a second embodiment will be described. FIGS. 8A and 8B are step cross-sectional views illustrating other steps for manufacturing the active matrix substrate 200. The manufacturing method according to the second embodiment is different from the manufacturing method according to the first embodiment in that after a connection electrode 14 is formed, a portion D_{H} of a drain region 4d that overlaps a drain contact hole CH_{D} is doped with impurities. That is, steps other than the steps illustrated in FIGS. 7A and 7B are the same as those according to the first embodiment. Steps and effects common to those in the first embodiment will not be described again.

In the manufacturing method in the second embodiment, after the drain contact hole CH_{D} is formed (see FIG. 6D), the connection electrode 14 is formed as illustrated in FIG. 8A. The method for forming the connection electrode 14 is the same as that in the first embodiment. The connection electrode 14 is in contact with a portion D_{H} of the drain region 4d that overlaps the drain contact hole CH_{D} in the drain contact hole CH_{D}.

Thereafter, as illustrated in FIG. 8B, impurities are doped from above the connection electrode 14 and a second interlayer insulating layer 9. The doping of impurities is similar to that in the first embodiment. For example, the second interlayer insulating layer 9, a first interlayer insulating layer 8, and an upper gate insulating layer 5 have sufficient thicknesses, so that the impurity ions injected from above these insulating layers do not reach the oxide semiconductor layer 4. In contrast, in the drain contact hole CH_{D}, the second interlayer insulating layer 9, the first interlayer insulating layer 8, and the upper gate insulating layer 5 are removed, and the connection electrode 14 is sufficiently thin compared to the first interlayer insulating layer 8 and the second interlayer insulating layer 9. Therefore, in the drain contact hole CH_{D} from which the insulating layers are removed, impurity ions pass through the connection electrode 14 and are doped into the portion D_{H} of the oxide semiconductor layer 4 that overlaps the drain contact hole CH_{D}.

This method also makes it possible to selectively increase the impurity concentration in the portion D_{H} of the drain region 4d that overlaps the drain contact hole CH_{D}. As a result, the contact resistance of the portion D_{H} of the oxide semiconductor layer 4 that is exposed through the drain contact hole CH_{D} and oxidized is reduced.

The subsequent steps may be the same as those in the first embodiment (see FIGS. 7C to 7D, FIG. 3, etc.). Thus, the active matrix substrate 200 can be manufactured.

### Third Embodiment

### Manufacturing Method 3: Activation of Oxide Semiconductor Layer by Plasma Process 1

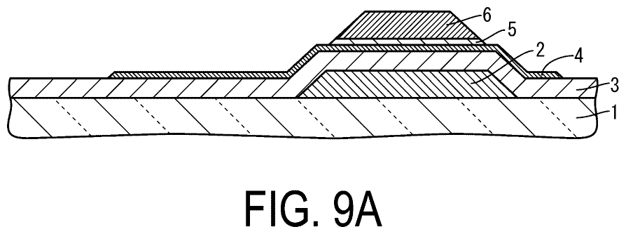

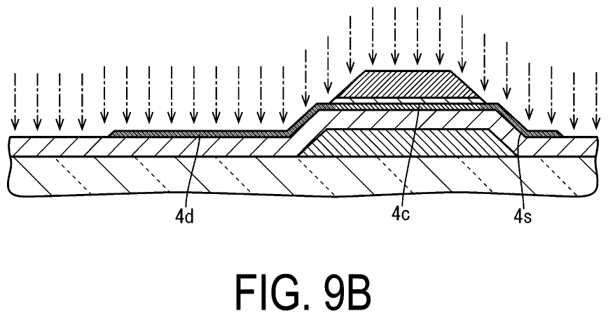

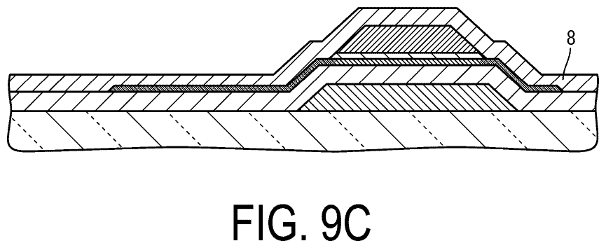

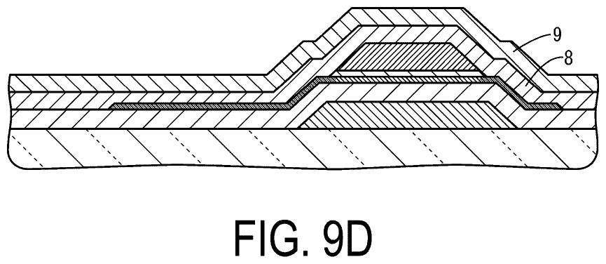

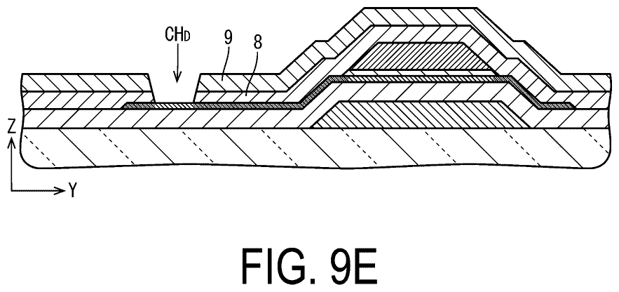

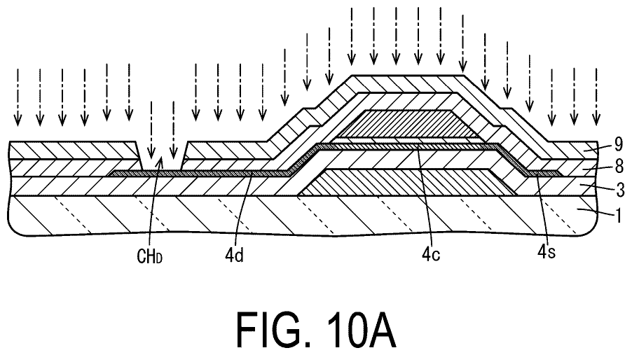

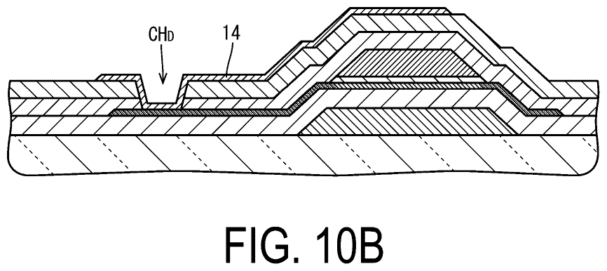

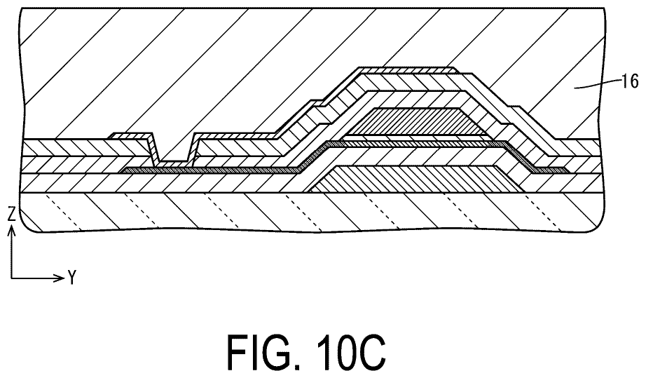

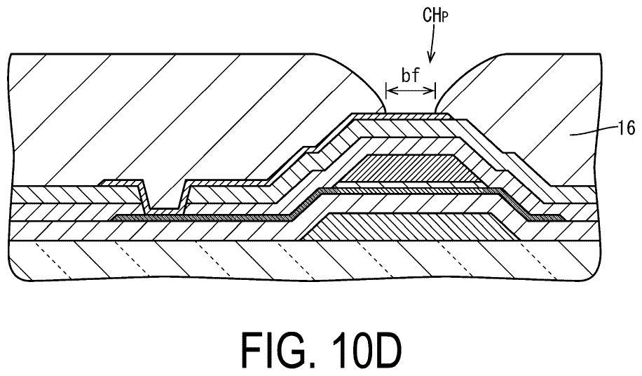

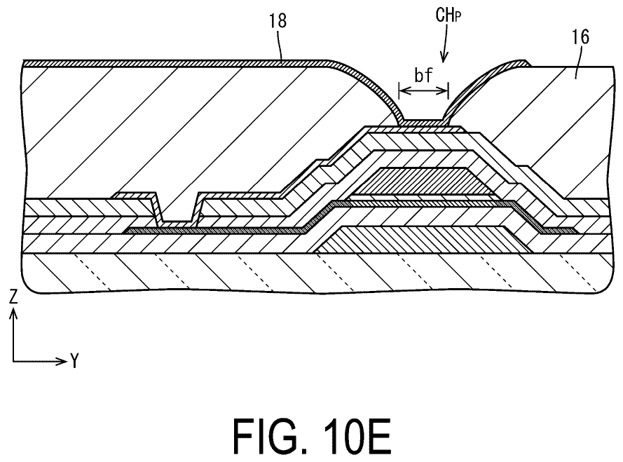

An active matrix substrate 300 and a method for manufacturing thereof according to a third embodiment will be described. FIGS. 9A to 10E are step cross-sectional views illustrating other steps for manufacturing the active matrix substrate 300. The manufacturing method according to the third embodiment is different from the manufacturing method according to the first embodiment in that an oxide semiconductor layer 4 is activated by a plasma process. Steps and effects common to those according to the first embodiment will not be described again.

That is, steps up to formation of an upper gate insulating layer 5 are the same as those in the first embodiment (see FIGS. 5A to 5E).

In the manufacturing method in the third embodiment, thereafter, as illustrated in FIG. 9A, a source region 4s and a drain region 4d of the oxide semiconductor layer 4 are exposed. For example, the source region 4s and the drain region 4d can be exposed by removing the upper gate insulating layer 5 at portions that cover at least the source region 4s and the drain region 4d by patterning using a photolithography process. Note that in the step of forming the upper gate insulating layer 5 in FIG. 5E, the upper gate insulating layer 5 may be patterned together with the upper gate metal film. In this case, the step in FIG. 9A can be omitted.

Subsequently, as illustrated in FIG. 9B, a resistance reduction process is performed on the exposed oxide semiconductor layer 4. Here, for example, a plasma process is performed on the oxide semiconductor layer 4 using an upper gate electrode 6 as a mask. In the plasma process, the exposed oxide semiconductor layer 4 is exposed to an atmosphere in which, for example, argon (Ar) plasma, ammonia (NH₃) plasma, hydrogen (H) plasma, or a mixture of these plasmas is generated. Thus, the oxide semiconductor layer 4 is modified and a carrier density is increased. By such a plasma process, regions of the oxide semiconductor layer 4 that do not overlap the upper gate insulating layer 5 or an upper gate electrode 6 (regions that become the source region 4s and the drain region 4d) are low-resistive regions having a lower specific resistance than a resistance in a region of the oxide semiconductor layer 4 that overlaps the upper gate insulating layer 5 and the upper gate electrode 6 (a region that becomes a channel region 4c). As a result, the source region 4s and the drain region 4d are formed.

Subsequently, as illustrated in FIG. 9C, a first interlayer insulating layer 8 is formed to cover the exposed oxide semiconductor layer 4 and the upper gate electrode 6, a source contact hole CHs is formed, and a source electrode 7 and a source wiring line SL (i.e., a source metal layer) are formed on the first interlayer insulating layer 8. Further, as illustrated in FIG. 9D, a second interlayer insulating layer 9 is formed to cover a TFT 10. Thereafter, as illustrated in FIG. 9E, a drain contact hole CH_{D} is formed in the first interlayer insulating layer 8 and the second interlayer insulating layer 9 so that a portion of the drain region 4d of the oxide semiconductor layer 4 is exposed. Thus, a surface of the portion of the drain region 4d of the oxide semiconductor layer 4 exposed through the drain contact hole CH_{D} is oxidized. Although the upper gate insulating layer 5 is not provided, the steps illustrated in FIGS. 9C to 9E can be performed similarly to the steps illustrated in FIGS. 6B to 6D in the first embodiment.

Thereafter, as illustrated in FIG. 10A, in a substrate 1 with the drain contact hole CH_{D} have been formed, impurities are doped from above the second interlayer insulating layer 9. Subsequently, as illustrated in FIG. 10B, a connection electrode 14 is formed on the second interlayer insulating layer 9. Subsequently, as illustrated in FIG. 10C, a flattened layer 16 is formed to cover the second interlayer insulating layer 9 and the connection electrode 14. Then, as illustrated in FIG. 10D, a pixel contact hole CH_{P} is formed in the flattened layer 16. Thereafter, as illustrated in FIG. 10E, a pixel electrode 18 is formed on the flattened layer 16. Although the upper gate insulating layer 5 is not provided, the steps illustrated in FIGS. 10A to 10E can be performed similarly to the steps illustrated in FIGS. 7A to 7D and FIG. 3 in the first embodiment. Thus, the active matrix substrate 300 can be manufactured.

### Fourth Embodiment

### Manufacturing Method 4: Activation of Oxide Semiconductor Layer by Plasma Process 2

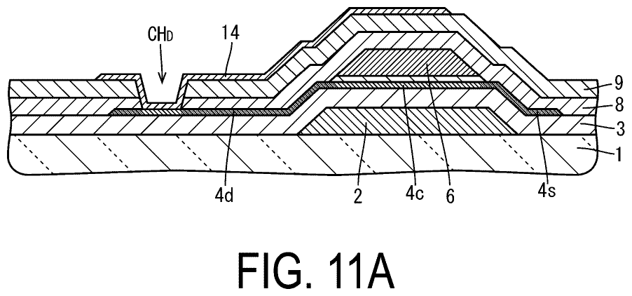

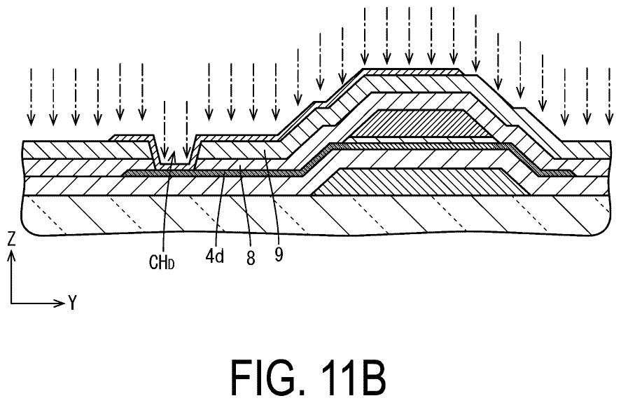

Another method for manufacturing an active matrix substrate 400 according to a fourth embodiment will be described. FIGS. 11A and 11B are step cross-sectional views illustrating other steps for manufacturing the active matrix substrate 400. The manufacturing method according to the fourth embodiment is different from the manufacturing method according to the third embodiment in that after a connection electrode 14 is formed, a portion D_{H} of a drain region 4d that overlaps a drain contact hole CH_{D} is doped with impurities. That is, steps other than the steps illustrated in FIGS. 11A and 11B can be performed in a manner similar to that in the first to third embodiments. In the following, steps and effects common to those in the first to third embodiments will not be described again.

In the manufacturing method in the fourth embodiment, after the drain contact hole CH_{D} is formed (see FIG. 9E), the connection electrode 14 is formed as illustrated in FIG. 11A. Thereafter, as illustrated in FIG. 11B, impurities are doped from above the connection electrode 14 and a second interlayer insulating layer 9. For example, the second interlayer insulating layer 9 and a first interlayer insulating layer 8 have sufficient thicknesses, so that impurity ions injected from above these insulating layers do not reach the oxide semiconductor layer 4. In contrast, in the drain contact hole CH_{D}, the second interlayer insulating layer 9 and the first interlayer insulating layer 8 are removed, and the connection electrode 14 is sufficiently thin compared to the first interlayer insulating layer 8 and the second interlayer insulating layer 9. Therefore, in the drain contact hole CH_{D} from which the insulating layers are removed, impurity ions pass through the connection electrode 14 and are doped into the portion D_{H} of the oxide semiconductor layer 4 that overlaps the drain contact hole CH_{D}.

This method also makes it possible to selectively increase the impurity concentration in the portion D_{H} of the drain region 4d that overlaps the drain contact hole CH_{D}. As a result, the contact resistance of the portion D_{H} of the oxide semiconductor layer 4 that is exposed through the drain contact hole CH_{D} and oxidized is reduced. Other steps may be similar to those in the first and third embodiments and the like. Thus, the active matrix substrate 400 can be manufactured.

### Fifth Embodiment

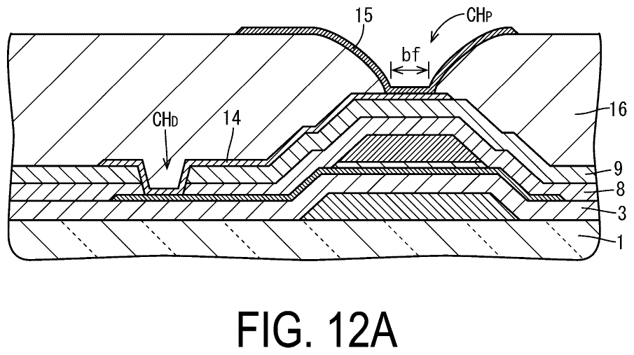

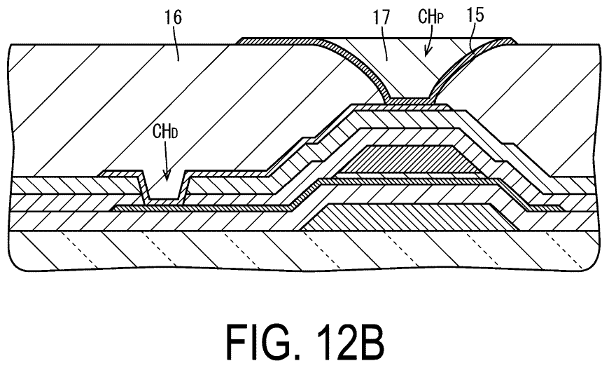

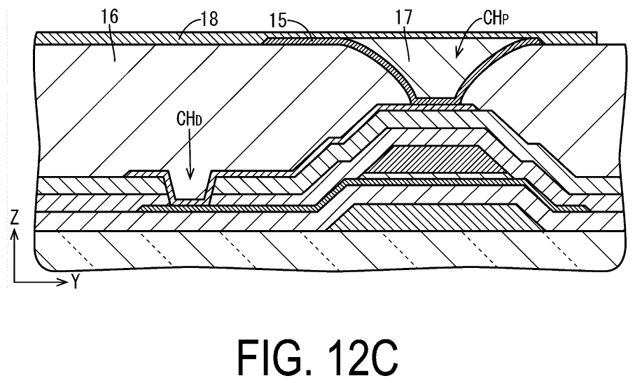

An active matrix substrate 500 and another method for manufacturing thereof according to a fifth embodiment will be described. The active matrix substrate 500 is different from the active matrix substrate 300 in the third embodiment in that, for example, as illustrated in FIG. 12C, the active matrix substrate 500 includes a further connection electrode 15 (another connection electrode in the present technology) and a further flattened layer 17 (another flattened layer in the present technology). In the following description, a connection electrode 14 and a flattened layer 16 are referred to as a “first connection electrode” and a “first flattened layer”, respectively, and the further connection electrode 15 and the further flattened layer 17 are referred to as a “second connection electrode” and a “second flattened layer”, respectively. Note that although not specifically described, for example, the active matrix substrate 100 according to the first embodiment may include the connection electrode 15 and the further flattened layer 17 in a similar manner.

Such an active matrix substrate 500 in the fifth embodiment can be manufactured, for example, by the following manufacturing method. FIGS. 12A to 12C are cross-sectional views illustrating steps for manufacturing the active matrix substrate 500 according to the fifth embodiment. Note that steps up to formation of the pixel contact hole CH_{D} may be the same as those according to, for example, the third embodiment and the like. Regarding the active matrix substrate 500, the description of a configuration, manufacturing steps, and effects common to those of the active matrix substrates according to the first to fourth embodiments will be omitted.

That is, as illustrated in FIG. 12A, the second connection electrode 15 is formed on the first flattened layer in which the pixel contact hole CH_{D} is formed so as to cover the pixel contact hole CH_{D}. The second connection electrode 15 is formed from a transparent conductive material, and electrically connects the first connection electrode 14 and a pixel electrode 18. The second connection electrode 15 is in contact with the first connection electrode 14 in the pixel contact hole CH_{D}.

Subsequently, as illustrated in FIG. 12B, the second flattened layer 17 is formed on the second connection electrode 15. The second flattened layer 17 is formed so as to fill the pixel contact hole CH_{D}. The second flattened layer 17 covers a portion of the second connection electrode 15. The second flattened layer 17 is formed from, for example, a photosensitive resin material.

Then, as illustrated in FIG. 12C, the pixel electrode 18 is formed so as to overlap the second flattened layer 17. The pixel electrode 18 is in contact with at least a portion of the second connection electrode 15 that is not covered with the second flattened layer 17. The pixel electrode 18 includes a portion positioned on the second flattened layer 17. The second connection electrode 15 and the pixel electrode 18 are formed from the same transparent conductive material. Here, the second connection electrode 15 and the pixel electrode 18 are formed from indium tin oxide.

In the active matrix substrate 500 according to the fifth embodiment, the second flattened layer 17 is formed so as to fill the pixel contact hole CH_{P}, and the pixel electrode 18 includes a portion positioned on the second flattened layer 17, thereby suppressing alignment disorder of liquid crystal molecules caused by the pixel contact hole CH_{D}. This can further improve transmittance.

### Oxide Semiconductor

An oxide semiconductor included in the oxide semiconductor layer 4 may be an amorphous oxide semiconductor, or may be a crystalline oxide semiconductor including a crystalline portion. Examples of the crystalline oxide semiconductor include a polycrystalline oxide semiconductor, a microcrystalline oxide semiconductor, and a crystalline oxide semiconductor having a c-axis oriented substantially perpendicular to the layer surface.

The oxide semiconductor layer 4 may have a layered structure including two or more layers. The oxide semiconductor layer 4 having a layered structure may include an amorphous oxide semiconductor layer and a crystalline oxide semiconductor layer, and may include a plurality of crystalline oxide semiconductor layers having different crystal structures. In addition, the oxide semiconductor layer 4 having a layered structure may include a plurality of amorphous oxide semiconductor layers. When the oxide semiconductor layer 4 has a layered structure, energy gaps of the respective layers may be different from each other.

Materials, structures, and film formation methods of an amorphous oxide semiconductor and the above-described each of crystalline oxide semiconductors, a configuration of an oxide semiconductor layer having a layered structure, and the like are described in, for example, JP 2014-007399 A. The entire contents of the disclosure of JP 2014-007399 A are incorporated herein by reference.

The oxide semiconductor layer 4 may include, for example, at least one metal element among In, Ga, and Zn. In the above-described embodiments, the oxide semiconductor layer 4 includes, for example, an In—Ga—Zn—O based semiconductor (for example, indium gallium zinc oxide). Here, the In—Ga—Zn—O based semiconductor is a ternary oxide of In (indium), Ga (gallium), and Zn (zinc), there is no particular limitation on a ratio (composition ratio) of In, Ga, and Zn, and examples of the ratio include In:Ga:Zn=2:2:1, In:Ga:Zn=1:1:1, In:Ga:Zn=1:1:2, and the like. Such an oxide semiconductor layer 4 can be formed of an oxide semiconductor film including an In—Ga—Zn—O based semiconductor.

The In—Ga—Zn—O based semiconductor may be an amorphous semiconductor or may be a crystalline semiconductor. A crystalline In—Ga—Zn—O based semiconductor in which a c-axis is oriented substantially perpendicular to a layer surface is preferable as the crystalline In—Ga—Zn—O based semiconductor.

Note that a crystal structure of the crystalline In—Ga—Zn—O based semiconductor is disclosed in, for example, JP 2014-007399 A as described above, JP 2012-134475 A, and JP 2014-209727 A. The entire contents of the disclosure of JP 2012-134475 A and JP 2014-209727 A are incorporated herein by reference. A TFT including an In—Ga—Zn—O based semiconductor layer has a high mobility (more than 20 times as compared to an a-Si TFT) and a low leakage current (less than 1/100 as compared to the a-Si TFT). Thus, such a TFT can be suitably used as a drive TFT (for example, a TFT included in a drive circuit provided in a periphery of a display region including a plurality of pixels, and on the same substrate as the display region) and a pixel TFT (TFT provided in a pixel).

In place of the In—Ga—Zn—O based semiconductor, the oxide semiconductor layer 4 may include another oxide semiconductor. The oxide semiconductor layer 4 may include, for example, an In—Sn—Zn—O based semiconductor (e.g., In₂O₃—SnO₂—ZnO; InSnZnO). The In—Sn—Zn—O based semiconductor is a ternary oxide of In (indium), Sn (tin), and Zn (zinc). Alternatively, the oxide semiconductor layer 4 may include an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, and an In—Ga—Zn—Sn—O based semiconductor.

### Liquid Crystal Display Device

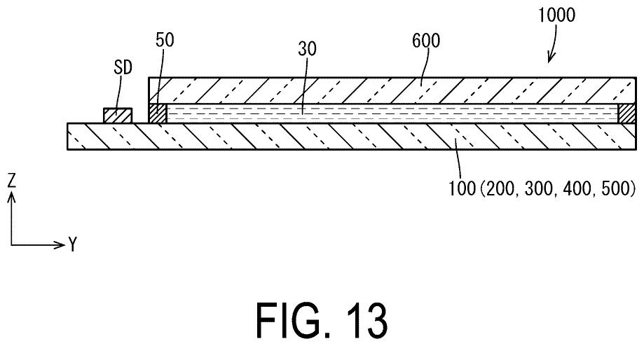

The active matrix substrates 100, 200, 300, 400, and 500 according to the embodiments of the disclosure can be suitably used in liquid crystal display devices. FIG. 13 illustrates an example of the liquid crystal display device.

A liquid crystal display device 1000 illustrated in FIG. 13 includes the active matrix substrate 100 (or the active matrix substrate 200, 300, 400, or 500), a counter substrate 600 located so as to face the active matrix substrate 100, and a liquid crystal layer 30 located between the active matrix substrate 100 and the counter substrate 600.

The active matrix substrate 100 includes the TFTs 10 (not illustrated here) located in the pixel regions P, respectively, the pixel electrodes 18 electrically connected to the TFTs 10, respectively, a dielectric layer (not illustrated) located so as to cover the pixel electrodes 18, and a common electrode (not illustrated) located on the dielectric layer and facing the pixel electrodes 18. At least one slit (not illustrated) is formed in the common electrode for each pixel region P.

Alignment films (not illustrated) are located on the outermost surfaces of the active matrix substrate 100 and the counter substrate 600 on the liquid crystal layer 30 side, respectively. The counter substrate 600 typically includes a color filter layer and a black matrix (neither of which are illustrated).

A thickness (cell gap) of the liquid crystal layer 30 is defined by columnar spacers 50 included in the counter substrate 600 on the liquid crystal layer 30 side. Spacer receiving portions (not illustrated) may be included on the active matrix substrate side.

Note that, although the liquid crystal display device 1000 in an FFS mode, which is a type of transverse electrical field mode, is exemplified here, the active matrix substrates according to the embodiments of the disclosure may be used for liquid crystal display devices in other display modes. In a liquid crystal display device of a vertical electrical field mode such as a twisted nematic (TN) mode or a vertical alignment (VA) mode, a common electrode is provided on a counter substrate side. The active matrix substrate 100 according to the present technology is particularly suitable for use in high-resolution (e.g., 1000 ppi or more) liquid crystal display devices such as the liquid crystal display device 1000 for, for example, a head-mounted display.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. An active matrix substrate including a display region including a plurality of pixel regions, the active matrix substrate comprising:
a substrate;
thin film transistors (TFTs) supported by the substrate and located in the plurality of pixel regions, respectively;
an insulating layer covering the TFTs;
a flattened layer covering the insulating layer;
pixel electrodes located on the flattened layer; and
connection electrodes located between the insulating layer and the flattened layer, and configured to electrically connect the TFTs and the pixel electrodes, respectively,
wherein each of the TFTs includes
a gate electrode,
a gate insulating layer configured to electrically insulate the gate electrode, and
an oxide semiconductor layer including a channel region facing the gate electrode with the gate insulating layer interposed between the channel region and the gate electrode, and a source region located on one side of the channel region and a drain region located on another side of the channel region,
the insulating layer includes a contact hole at a position overlapping with the drain region,
the connection electrodes are formed from a transparent conductive material and each of the connection electrodes is connected to the drain region in the contact hole, and
the drain region has a higher concentration of impurities at least in a portion overlapping the contact hole than a concentration in a portion adjacent to the channel region.

2. The active matrix substrate according to claim 1,
wherein each of the impurities is at least one of group 13 elements and group 15 elements.

3. The active matrix substrate according to claim 1,
wherein the connection electrodes include at least one of indium tin oxide (ITO) and indium zinc oxide (IZO), and
the oxide semiconductor layer includes an In—Ga—Zn—O-based oxide semiconductor.

4. The active matrix substrate according to claim 1,
wherein as viewed from a normal direction of the substrate, the flattened layer includes pixel contact holes, each of the pixel contact holes being configured to connect each of the pixel electrodes and each of the connection electrodes at a position at least partially overlapping with the gate electrode.

5. The active matrix substrate according to claim 4,
wherein as viewed from the normal direction of the substrate, a bottom face of each of the pixel contact holes at least partially overlaps a gate metal layer including the gate electrode.

6. The active matrix substrate according to claim 4,
wherein a portion of each of the pixel electrodes is in contact with each of the connection electrodes in each of the pixel contact holes.

7. The active matrix substrate according to claim 4, further comprising:
other connection electrodes formed from a transparent conductive material and configured to electrically connect the connection electrodes and the pixel electrodes, respectively, each of the other connection electrodes being in contact with each of the connection electrodes in each of the pixel contact holes; and
another flattened layer configured to fill the pixel contact holes and cover portions of the other connection electrodes,
wherein each of the pixel electrodes is in contact with a portion of each of the other connection electrodes, the portion being not covered with the other flattened layer, and
each of the pixel electrodes includes a portion located on the other flattened layer.

8. The active matrix substrate according to claim 7,
wherein the other connection electrodes and the pixel electrodes are formed from the same transparent conductive material.

9. The active matrix substrate according to claim 8,
wherein the other connection electrodes and the pixel electrodes are formed from at least one of indium tin oxide and indium zinc oxide.

10. The active matrix substrate according to claim 1,
wherein each of the TFTs includes
a lower gate electrode located on the substrate,
a lower gate insulating layer covering the lower gate electrode,
the oxide semiconductor layer, the channel region of the oxide semiconductor layer being located on the lower gate insulating layer,
an upper gate insulating layer located on the channel region of the oxide semiconductor layer, and
an upper gate electrode located on the upper gate insulating layer and facing the channel region of the oxide semiconductor layer with the upper gate insulating layer interposed between the upper gate electrode and the channel region.

11. The active matrix substrate according to claim 10,
wherein as viewed from a normal direction of the substrate, the flattened layer includes pixel contact holes, each of the pixel contact holes being configured to electrically connect each of the pixel electrodes and each of the connection electrodes at a position at least partially overlapping with the upper gate electrode, and
a bottom face of each of the pixel contact holes at least partially overlaps both the lower gate electrode and the upper gate electrode.

12. A liquid crystal display device comprising:
the active matrix substrate according to claim 1;
a counter substrate located facing the active matrix substrate; and
a liquid crystal layer located between the active matrix substrate and the counter substrate.

13. A method for manufacturing an active matrix substrate, comprising:
forming a thin film transistor (TFT) on a substrate, the TFT including
a gate electrode,
a gate insulating layer configured to electrically insulate the gate electrode, and
an oxide semiconductor layer including a channel region facing the gate electrode with the gate insulating layer interposed between the channel region and the gate electrode, and a source region located on one side of the channel region and a drain region located on another side of the channel region,
forming an insulating layer on the TFT;
forming a contact hole in the insulating layer, the contact hole being configured to reach the drain region;
doping impurities through the contact hole into a portion of the drain region overlapping the contact hole;
forming a connection electrode on the insulating layer at least from the contact hole to a position overlapping the gate electrode, the connection electrode being configured to electrically connect the TFT and a pixel electrode; and
forming a flattened layer on the insulating layer and the connection electrode.

14. The method for manufacturing an active matrix substrate according to claim 13,
wherein the TFT includes
a lower gate electrode located on the substrate,
a lower gate insulating layer covering the lower gate electrode,
the oxide semiconductor layer, the channel region of the oxide semiconductor layer being located on the lower gate insulating layer,
an upper gate insulating layer located on the channel region of the oxide semiconductor layer, and
an upper gate electrode located on the upper gate insulating layer and facing the channel region of the oxide semiconductor layer with the upper gate insulating layer interposed between the upper gate electrode and the channel region, the method comprising:
forming the connection electrode on the insulating layer at least from the contact hole to a position overlapping the upper gate electrode.

15. The method for manufacturing an active matrix substrate according to claim 14, further comprising:
forming a pixel contact hole in the flattened layer at a position overlapping the gate electrode or the upper gate electrode and the connection electrode, the pixel contact hole reaching the connection electrode; and
forming a pixel electrode on the flattened layer at a position at least partially overlapping the connection electrode through the pixel contact hole.

16. The method for manufacturing an active matrix substrate according to claim 14, further comprising:
forming a pixel contact hole in the flattened layer at a position overlapping the gate electrode or the upper gate electrode and the connection electrode, the pixel contact hole reaching the connection electrode;
forming another connection electrode on the flattened layer at a position at least partially overlapping the connection electrode through the pixel contact hole;
forming another flattened layer configured to fill the pixel contact hole; and
forming a pixel electrode on at least one of the flattened layer and the other flattened layer at a position at least partially overlapping the other connection electrode.
